(19) United States
(12) Patent Application Publication
(10) Pub. No.: US 2025/0259877 A1
(43) Pub. Date: Aug. 14, 2025

(54) SEMICONDUCTOR DEVICE AND MANUFACTURING METHOD OF SEMICONDUCTOR DEVICE

(71) Applicant: Kioxia Corporation, Tokyo (JP)

(72) Inventors: Aoi SUZUKI, Yokkaichi Mie (JP); Takuro OKUBO, Yokkaichi Mie (JP); Tomoyuki TAKEISHI, Yokkaichi Mie (JP); Ai MORI, Yokkaichi Mie (JP)

(73) Assignee: Kioxia Corporation, Tokyo (JP)

(21) Appl. No.: 19/193,508

(22) Filed: Apr. 29, 2025

Related U.S. Application Data
(62) Division of application No. 17/902,692, filed on Sep. 2, 2022.

(30) Foreign Application Priority Data
Dec. 14, 2021 (JP) 2021-202458

(51) Int. Cl. H01L 21/683; B32B 3/30; B32B 43/00; H01L 21/02

(52) U.S. Cl. CPC H01L 21/6835; B32B 3/30; B32B 43/006; H01L 21/02079; B32B 2310/0843; B32B 2457/14; H01L 2221/6839

(57) ABSTRACT

A manufacturing method of a semiconductor device includes stacking a first film on a first substrate and stacking a third film and a second film on a second substrate; joining a main surface on an opposite side of the first substrate of the first film and a main surface on an opposite side of the second substrate of the second film; emitting infrared laser light from a side of the second substrate in such a manner that a focal point is placed in a vicinity of the second film; and peeling off the second substrate. Absorptance of the infrared laser light of the second film is higher than absorptance of the infrared laser light of the second substrate, and a thermal expansion coefficient of the third film is different from a thermal expansion coefficient of a film in contact with the third film.

### CROSS-REFERENCE TO RELATED APPLICATIONS

This application is a Divisional application of U.S. application Ser. No. 17/902,692, filed Sep. 2, 2022, which is based upon and claims the benefit of priority from Japanese Patent Application No. 2021-202458, filed on Dec. 14, 2021, the entire contents of both of which are incorporated herein by reference.

### FIELD

Embodiments described herein relate generally to a semiconductor device and a manufacturing method of the semiconductor device.

### BACKGROUND

In manufacturing of a semiconductor device, there is a case where two substrates are joined and then one of the two substrates is peeled off. It is desirable that this peeling of the substrate is appropriately performed.

### BRIEF DESCRIPTION OF THE DRAWINGS

FIG. 1 is a cross-sectional view illustrating a configuration of a semiconductor device according to an embodiment;

FIG. 2 is a flowchart illustrating a manufacturing method of the semiconductor device according to the embodiment;

FIG. 3A to FIG. 3F are cross-sectional views illustrating the manufacturing method of the semiconductor device according to the embodiment;

FIG. 4A and FIG. 4B are cross-sectional views illustrating the manufacturing method of the semiconductor device according to the embodiment;

FIG. 5A to FIG. 5C are cross-sectional views illustrating the manufacturing method of the semiconductor device according to the embodiment;

FIG. 6A to FIG. 6C are cross-sectional views illustrating the manufacturing method of the semiconductor device according to the embodiment;

FIG. 7 is a cross-sectional view illustrating the manufacturing method of the semiconductor device according to the embodiment;

FIG. 8 is a plan view illustrating the manufacturing method of the semiconductor device according to the embodiment;

FIG. 9A to FIG. 9E are cross-sectional views illustrating the manufacturing method of the semiconductor device according to the embodiment;

FIG. 10 is a cross-sectional view illustrating a manufacturing method of a semiconductor device according to a first modification example of the embodiment;

FIG. 11A to FIG. 11E are cross-sectional views illustrating the manufacturing method of the semiconductor device according to the first modification example of the embodiment;

FIG. 12A to FIG. 12D are cross-sectional views illustrating a manufacturing method of a semiconductor device according to a second modification example of the embodiment;

FIG. 13 is a cross-sectional view illustrating the manufacturing method of the semiconductor device according to the second modification example of the embodiment;

FIG. 14A to FIG. 14D are cross-sectional views illustrating a manufacturing method of a semiconductor device according to a third modification example of the embodiment;

FIG. 15 is a cross-sectional view illustrating the manufacturing method of the semiconductor device according to the third modification example of the embodiment;

FIG. 16A to FIG. 16E are cross-sectional views illustrating the manufacturing method of the semiconductor device according to the third modification example of the embodiment;

FIG. 17 is a cross-sectional view illustrating a configuration of a semiconductor device according to a fourth modification example of the embodiment;

FIG. 18 is a cross-sectional view illustrating the manufacturing method of the semiconductor device according to the fourth modification example of the embodiment; and

FIG. 19A to FIG. 19E are cross-sectional views illustrating the manufacturing method of the semiconductor device according to the fourth modification example of the embodiment.

### DETAILED DESCRIPTION

In general, according to one embodiment, there is provided a semiconductor device including a substrate, a first film, a second film, and a third film. The first film is arranged on a side of a main surface of the substrate. The second film is arranged on an opposite side of the substrate with the first film being interposed therebetween. A main surface of the second film is in contact with a main surface of the first film. The third film is arranged on an opposite side of the first film with the second film being interposed therebetween. A main surface on a side of the substrate of the third film has two-dimensionally-distributed protrusions or recesses. A main surface on an opposite side of the substrate of the third film is flat. Absorptance of infrared light of the second film is higher than absorptance of the infrared light of the third film. A thermal expansion coefficient of the third film is different from a thermal expansion coefficient of the second film.

Exemplary embodiments of a semiconductor device will be explained below in detail with reference to the accompanying drawings. The present invention is not limited to the following embodiments.

### Embodiment

A semiconductor device according to an embodiment is formed by joining of two substrates, and has a structure suitable for reusing of a substrate removed after the joining. Joining of two substrates is also referred to as bonding of two substrates.

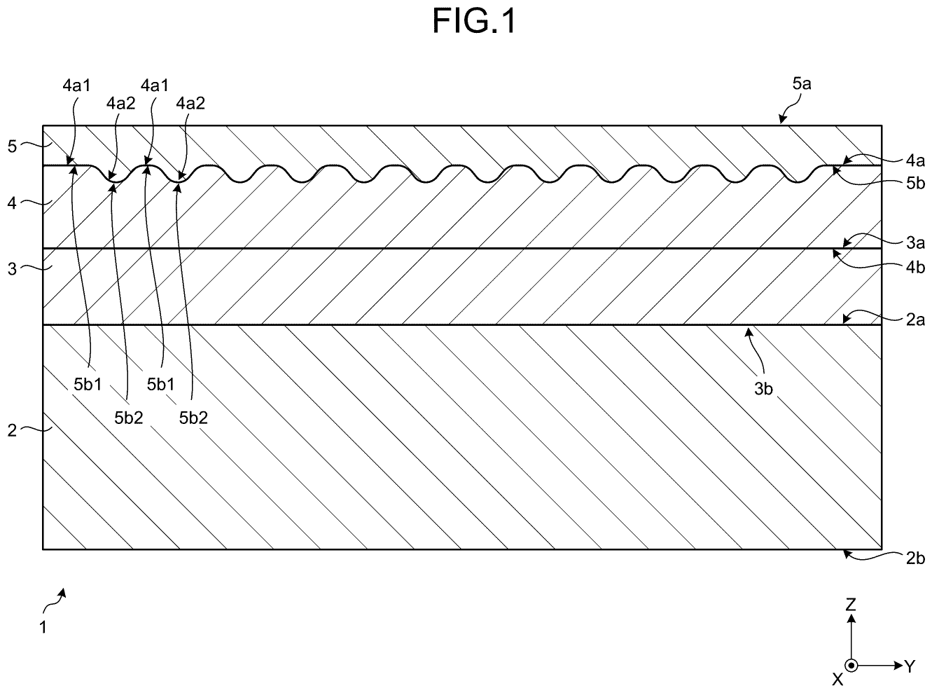

For example, a semiconductor device 1 is configured in a manner illustrated in FIG. 1. FIG. 1 is a cross-sectional view illustrating a configuration of the semiconductor device 1. In the following, it is assumed that a direction vertical to a main surface 2a of a substrate 2 is a Z direction, two directions orthogonal to each other in a plane vertical to the Z direction are an X direction and a Y direction.

As illustrated in FIG. 1, the semiconductor device 1 includes a substrate 2, a film 3, a film 4, and a film 5. The substrate 2 has a plate shape extending in an XY direction. The substrate 2 has a main surface 2a on a +Z side and a main surface 2b on a −Z side. Each of the main surface 2a and the main surface 2b extends in the XY direction. The substrate 2 is formed of a material including a semiconductor (such as silicon) as a main component.

The film 3 is arranged on the +Z side (side of the main surface 2a) of the substrate 2. The film 3 extends in the XY direction along the main surface 2a. The film 3 has a main surface 3a on the +Z side and a main surface 3b on the −Z side. Each of the main surface 3a and the main surface 3b extends in a substantially flat manner in the XY direction. The film 3 may be formed of a material including an insulator as a main component, or may be formed of a material including a semiconductor oxide (such as silicon oxide) as a main component.

Although a configuration in which the film 3 covers the main surface 2a of the substrate 2 is illustrated as an example in FIG. 1 for simplification, another film may be interposed between the film 3 and the substrate 2. For example, a three-dimensional memory cell array may be configured in the following manner. That is, a stacked body in which a conductive layer and an insulating layer are repeatedly stacked is arranged between the film 3 and the substrate 2, and a semiconductor film extends in the Z direction in the stacked body.

The film 4 is arranged on the opposite side of the substrate 2 with the film 3 being interposed therebetween. The film 4 is arranged on the +Z side of the substrate 2 and the film 3. The film 4 extends in the XY direction along the main surface 2a. The film 4 has a main surface 4a on the +Z side and a main surface 4b on the −Z side. Each of the main surface 4a and the main surface 4b extends in the XY direction. The film 4 may be formed of any material having infrared light absorptance higher than those of the substrate 2 and the film 5. The film 4 may be formed of any material having higher absorptance than the substrate 2 and the film 5 with respect to a laser wavelength suitable for the film 4 to function as a laser absorbing layer (preferably 1117 nm or higher, and more preferably around 9300 nm or around 10600 nm). The film 4 may be formed of a material including an insulator as a main component, or may be formed of a material including a semiconductor oxide (such as silicon oxide) as a main component.

The main surface 3a and the main surface 4b extend in a flat manner in the XY direction and are in contact with each other. Atoms of the main surface 3a of the film 3 and atoms of the main surface 4b of the film 4 may be bonded by a hydrogen bond or a covalent bond. The semiconductor device 1 is formed by joining of two substrates as described later, and the main surface 3a and the main surface 4b are joined surfaces.

The film 5 is arranged on the opposite side of the film 3 with the film 4 being interposed therebetween. The film 5 is arranged on the +Z side of the substrate 2, the film 3, and the film 4. The film 5 extends in the XY direction along the main surface 2a. The film 5 has a main surface 5a on the +Z side and a main surface 5b on the −Z side. Each of the main surface 5a and the main surface 5b extends in the XY direction. The main surface 5a extends in the XY direction in a flat manner.

The film 5 may be formed of any material having infrared light absorptance lower than that of the film 4, and a thermal expansion coefficient larger than the thermal expansion coefficient of the film 4. The film 5 may be formed of any material having lower absorptance than the film 4 with respect to the laser wavelength suitable for the film 4 to function as the laser absorbing layer (preferably 1117 nm or higher, and more preferably around 9300 nm or around 10600 nm) and a thermal expansion coefficient larger than the thermal expansion coefficient of the film 4.

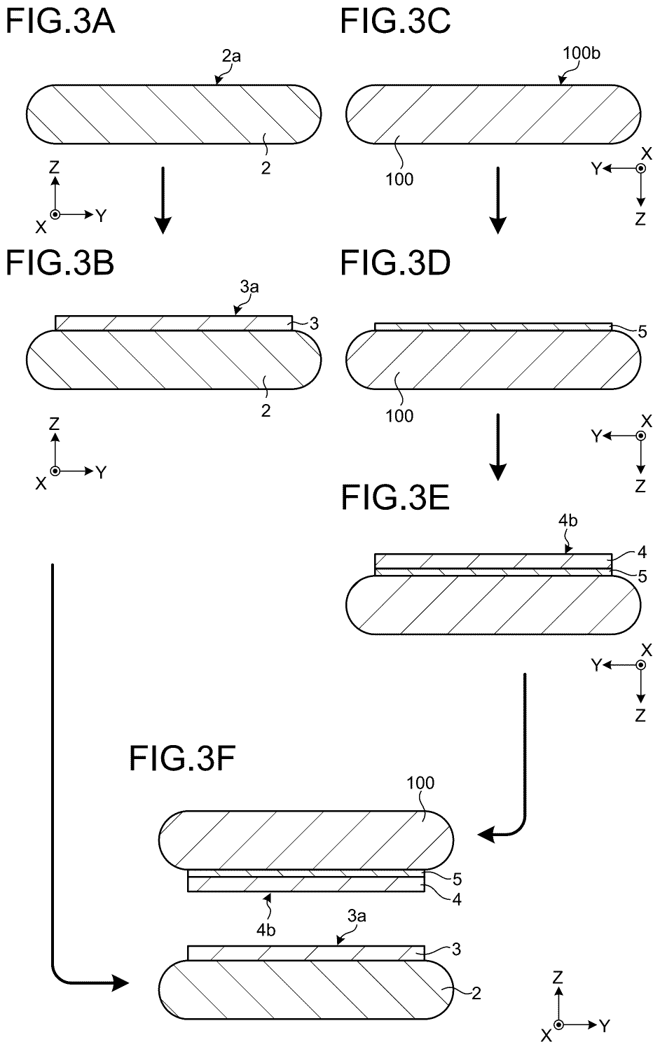

Note that the thermal expansion coefficient of the film 5 is larger than a thermal expansion coefficient of a substrate 100 arranged on the +Z side of the film 5 in a manufacturing process of the semiconductor device 1 (see FIG. 3F). However, since the substrate 100 does not remain in the structure of the semiconductor device 1, in a case where the substrate 100 is formed of the same material as the substrate 2, the thermal expansion coefficient of the film 5 is made larger than the thermal expansion coefficient of the substrate 2, whereby the thermal expansion coefficient of the film 5 can be indirectly made larger than the thermal expansion coefficient of the substrate 100.

In a case where the film 4 covers the main surface 5b of the film 5, the film 5 may be formed of any material having infrared light absorptance lower than that of the film 4, and a thermal expansion coefficient larger than that of the film 4. The film 5 may be formed of any material having lower absorptance than the film 4 with respect to the laser wavelength suitable for the film 4 to function as the laser absorbing layer (preferably 1117 nm or higher, and more preferably around 9300 nm or around 10600 nm) and a thermal expansion coefficient larger than that of the film 4. The film 5 may be formed of a material including a semiconductor polycrystalline material (such as polycrystalline silicon) as a main component, or may be formed of a material including a semiconductor amorphous material (such as amorphous silicon) as a main component.

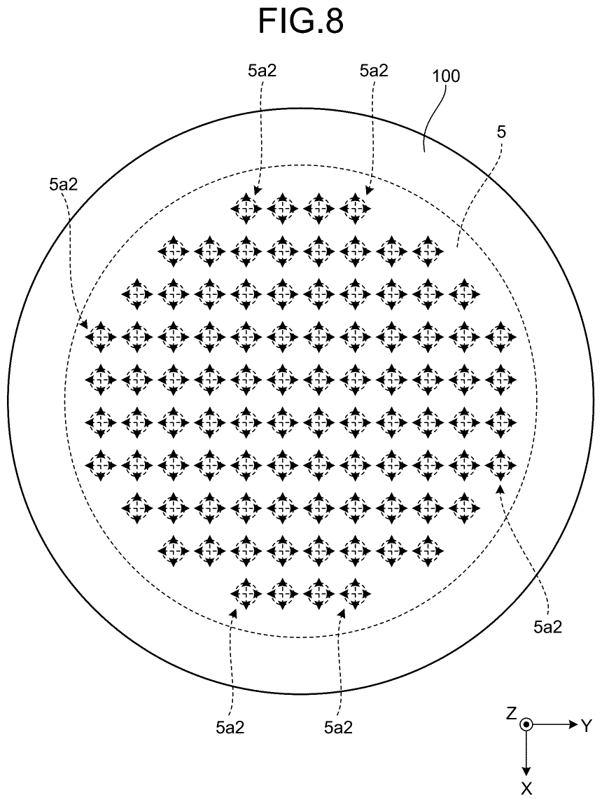

In a case where the film 4 covers the main surface 5b of the film 5, each of the main surface 4a and the main surface 5b has protrusions or recesses two-dimensionally distributed (see FIG. 8). The main surface 4a has a flat surface 4a1 and plural recesses 4a2. The flat surface 4a1 extends in the XY direction and configures a main portion of the main surface 4a. The recesses 4a2 are recessed from the flat surface 4a1 to the inside (−Z side) of the film 4. The main surface 5b has a flat surface 5b1 and plural protrusions 5b2. The flat surface 5b1 extends in the XY direction and configures a main portion of the main surface 5b. The plural protrusions 5b2 are arranged apart from each other in the XY direction. The protrusions 5b2 protrude from the flat surface 5b1 to the outside (−Z side) of the film 5 in a manner corresponding to the recesses 4a2.

Although a configuration in which the film 4 covers the main surface 5b of the film 5 is illustrated as an example in FIG. 1 for simplification, another film may be interposed between the film 4 and the film 5 as long as the film has a certain degree of thermal conductivity. For example, a control circuit to control a memory cell array may be configured by stacking of a semiconductor layer, a conductive layer, an insulating layer, and the like between the film 4 and the film 5 and forming of a CMOS structure. In that case, a main surface of another film which surface covers the main surface 5b of the film 5 may have recesses distributed two-dimensionally and corresponding to the main surface 4a illustrated in FIG. 1.

Note that as described later, in the manufacturing process of the semiconductor device 1, the film 4 functions as a laser absorbing layer, and the film 5 functions as a layer that receives local heat generation by the laser absorbing layer (film 4) and that performs local thermal expansion. Each of the plural protrusions 5b2 on the main surface 5b have a structure formed by the local thermal expansion.

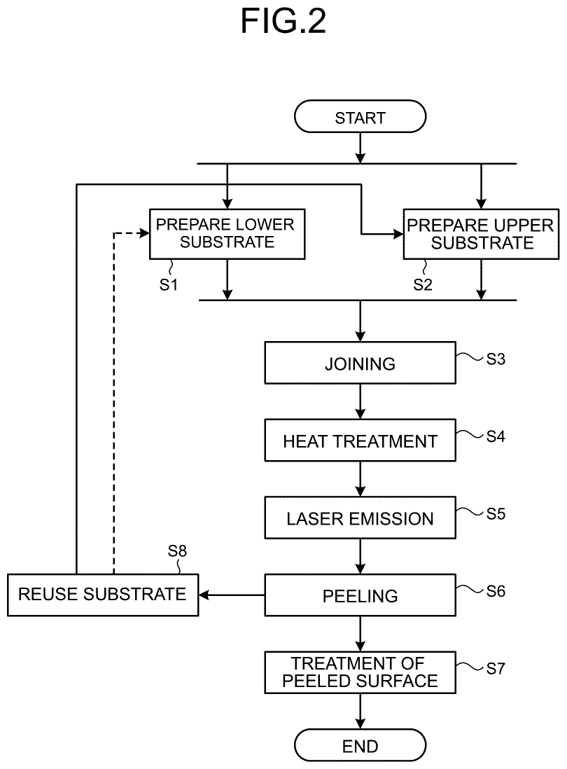

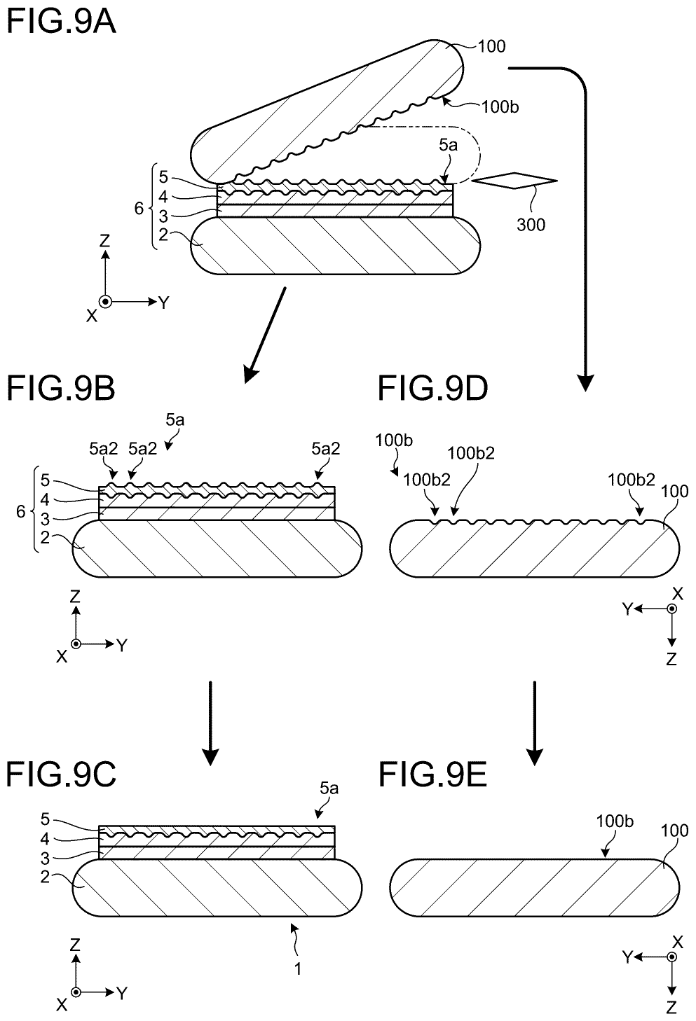

Next, a manufacturing method of the semiconductor device 1 will be described with reference to FIG. 2 to FIG. 9E. FIG. 2 is a flowchart illustrating the manufacturing method of the semiconductor device 1. FIG. 3A to FIG. 7, and FIG. 9A to FIG. 9E are YZ cross-sectional views illustrating the manufacturing method of the semiconductor device 1. FIG. 8 is an XY plan view illustrating the manufacturing method of the semiconductor device 1.

In the manufacturing method of the semiconductor device 1, as illustrated in FIG. 2, preparation of a lower substrate (S1) and preparation of an upper substrate (S2) are performed in parallel. Between the two substrates to be joined, the lower substrate is a substrate arranged on the −Z side at the time of joining. Between the two substrates to be joined, the upper substrate is a substrate arranged on the +Z side at the time of joining.

In the preparation of the lower substrate (S1), a substrate (lower substrate) 2 is prepared as illustrated in FIG. 3A. The substrate 2 may be formed of a material including a semiconductor substantially free of impurities (such as silicon) as a main component.

As illustrated in FIG. 3B, the film 3 is deposited on a side of the main surface 2a (+Z side) of the substrate 2 by a CVD method or the like. The film 3 may be formed of a material including an insulator as a main component, or may be formed of a material including a semiconductor oxide (such as silicon oxide) as a main component.

In the preparation of the upper substrate (S2), a substrate (upper substrate) 100 is prepared as illustrated in FIG. 3C. The substrate 100 may be formed of a material including a semiconductor substantially free of impurities (such as silicon) as a main component.

As illustrated in FIG. 3D, the film 5 is deposited on a side of the main surface 100b (−Z side) of the substrate 100 by the CVD method or the like. The film 5 may be formed of any material having infrared light absorptance lower than that of the film 4, and a thermal expansion coefficient larger than that of the substrate 100. The film 5 may be formed of any material having lower absorptance than the film 4 with respect to the laser wavelength suitable for the film 4 to function as the laser absorbing layer (preferably 1117 nm or higher, and more preferably around 9300 nm or around 10600 nm) and a thermal expansion coefficient larger than that of the substrate 100, for example. The film 5 may be formed of a material including a semiconductor polycrystalline material (such as polycrystalline silicon) as a main component, or may be formed of a material including a semiconductor amorphous material (such as amorphous silicon) as a main component.

As illustrated in FIG. 3E, the film 4 is deposited on the −Z side of the film 5 by the CVD method or the like. The film 4 may be formed of any material having infrared light absorptance higher than that of the film 5. The film 4 may be formed of any material having higher absorptance than the film 5 and the substrate 100 with respect to the laser wavelength suitable for the film 4 to function as the laser absorbing layer (preferably 1117 nm or higher, and more preferably around 9300 nm or around 10600 nm). The film 4 may be formed of a material including an insulator as a main component, or may be formed of a material including a semiconductor oxide (such as silicon oxide) as a main component.

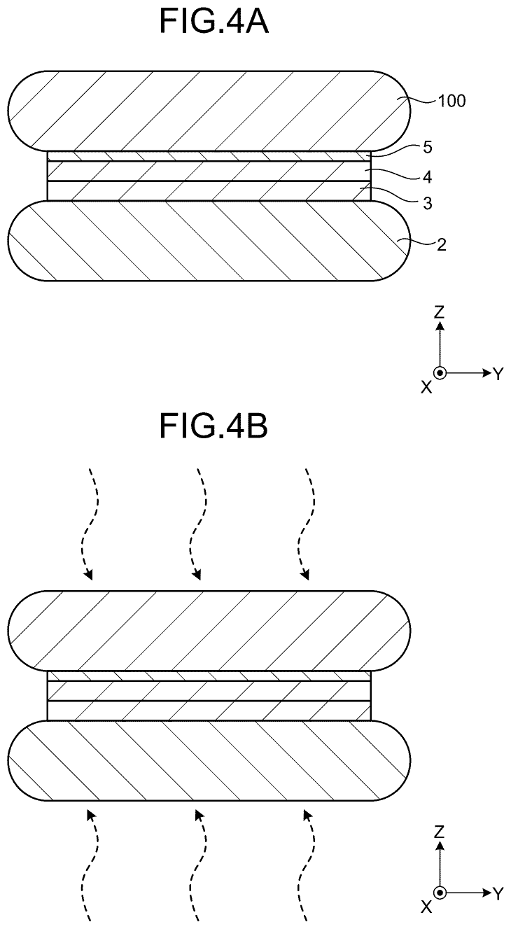

As illustrated in FIG. 2, when both the preparation of the lower substrate (S1) and the preparation of the upper substrate (S2) are completed, the upper substrate and the lower substrate are joined (S3). Each of the main surface 3a on the +Z side of the film 3 (see FIG. 3B) and the main surface 4b on the −Z side of the film 4 (see FIG. 3E) is activated by plasma irradiation or the like, and the substrate 2 and the substrate 100 are arranged in a manner of facing each other in the Z direction in such a manner that the main surface 3a and the main surface 4b face each other as illustrated in FIG. 3F. As illustrated in FIG. 4A, the substrate 2 and the substrate 100 are brought close to each other in the Z direction, and the main surface 3a on the side of the substrate 2 and the main surface 4b on the side of the substrate 100 are joined. At this time, atoms of the main surface 3a and atoms of the main surface 4b are bonded by the hydrogen bond or the like, and the substrate 2 and the substrate 100 are temporarily joined.

Thus, heat treatment (annealing) at a relatively low temperature is performed (S4) as illustrated in FIG. 2. In the heat treatment (annealing), the substrate 2 and the substrate 100 are heated as a whole as indicated by dotted arrows in FIG. 4B. In the heat treatment, for example, each of the substrate 2 and the substrate 100 is heated to a relatively low temperature (that is, allowable temperature of a device structure, such as about 200° C.) for a predetermined time. At this time, the atoms of the main surface 3a and the atoms of the main surface 4b are bonded to each other by covalent bond or the like as water molecules escape from the interface, and the substrate 2 and the substrate 100 are brought into a state of being finally joined.

When S4 illustrated in FIG. 2 is completed, infrared laser light 200 is emitted from the side of the substrate 100 in such a manner that a focal point is placed in the vicinity of the film 4 (S5). The laser light emission is performed with the infrared laser light 200 in the wavelength in which light absorptance of the film 4 that is the laser absorbing layer is higher than those of the other film 5 and the substrate 100 (preferably 1117 nm or higher, and more preferably near 9300 nm or near 10600 nm in a case where the laser absorbing layer is a silicon oxide film). A pulsed laser is used as the infrared laser light 200. Absorption of the infrared laser light 200 occurs depending on an absorption coefficient and thickness of a substrate or film, and laser absorption occurs the most in the film 4 that functions as the laser absorbing layer in the present structure. A pulse width of the infrared laser light 200 may be a low frequency of about 1 to 100 kHz.

At this time, the emission of the infrared laser light 200 is performed in such a manner that plural irradiated portions are two-dimensionally distributed in the film 4. The emission of the infrared laser light 200 is performed in such a manner that the plural irradiated portions are apart from each other in an XY plane direction (see FIG. 8). The emission of the infrared laser light 200 is adjusted to emission intervals suitable for peeling in consideration of heat storage influence due to the local heat generation in the film 4.

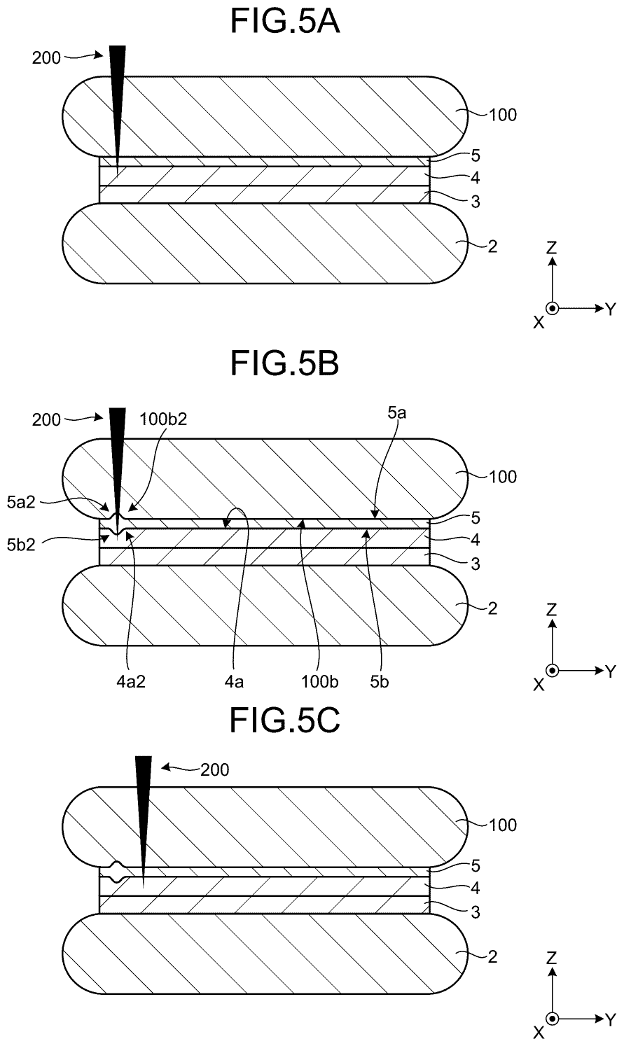

For example, as illustrated in FIG. 5A, an XY plane position to be irradiated with the infrared laser light 200 is determined, and the adjustment is performed in such a manner that the focal point of the infrared laser light 200 is placed in the film 4. Absorptance of the infrared laser light 200 of the film 4 is higher than absorptance of the infrared laser light 200 of the substrate 100, and is higher than absorptance of the infrared laser light 200 of the film 5. As a result, the infrared laser light 200 emitted to the film 4 through the substrate 100 and the film 5 is efficiently absorbed by an irradiated point in the film 4, and the film 4 is made to locally generate heat (is locally heated) at the XY plane position.

The local heat generation by the film 4 is transmitted to the film 5 and causes the film 5 to expand at the XY plane position, as illustrated in FIG. 5B. The thermal expansion coefficient of the film 5 is larger than the thermal expansion coefficient of the substrate 100 and is larger than the thermal expansion coefficient of the film 4. As a result, at the XY plane position, due to the expansion of the film 5, protrusions 5a2 protruding to the +Z side in the main surface 5a on the +Z side and protrusions 4b2 protruding to the −Z side in the main surface 5b on the −Z side in the film 5 are formed. In a manner corresponding to the above, recesses 100b2 recessed to the +Z side in the main surface 100b on the −Z side of the substrate 100 is formed, and recesses 4a2 recessed to the −Z side in the main surface 4a on the +Z side of the film 4 is formed.

As illustrated in FIG. 5C, the XY plane position to be irradiated with the infrared laser light 200 is determined to a position shifted in the XY plane direction from the XY plane position in FIG. 5A, and the adjustment is performed in such a manner that the focal point of the infrared laser light 200 is placed in the film 4. The absorptance of the infrared laser light 200 of the film 4 is higher than the absorptance of the infrared laser light 200 of the substrate 100, and is higher than the absorptance of the infrared laser light 200 of the film 5. As a result, the infrared laser light 200 emitted to the film 4 through the substrate 100 and the film 5 is efficiently absorbed by an irradiated point in the film 4, and the film 4 is made to locally generate heat (is locally heated) at the XY plane position.

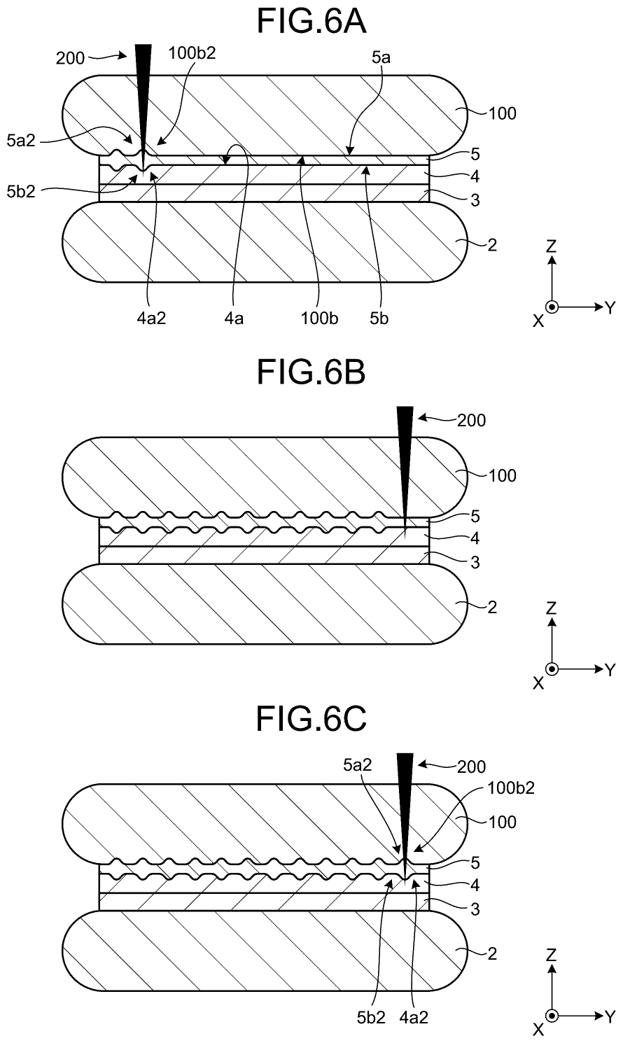

The local heat generation by the film 4 is transmitted to the film 5 and causes the film 5 to expand at the XY plane position, as illustrated in FIG. 6A. The thermal expansion coefficient of the film 5 is larger than the thermal expansion coefficient of the substrate 100 and is larger than the thermal expansion coefficient of the film 4. As a result, at the XY plane position, due to the expansion of the film 5, the protrusions 5a2 protruding to the +Z side in the main surface 5a on the +Z side and the protrusions 4b2 protruding to the −Z side in the main surface 5b on the −Z side in the film 5 are formed. In a manner corresponding to the above, the recesses 100b2 recessed to the +Z side in the main surface 100b on the −Z side of the substrate 100 is formed, and the recesses 4a2 recessed to the −Z side in the main surface 4a on the +Z side of the film 4 is formed.

Processing similar to that of FIG. 5C and FIG. 6A is repeated while the XY plane position to be irradiated is shifted.

As illustrated in FIG. 6B, a final XY plane position to be irradiated with the infrared laser light 200 is determined, and the adjustment is performed in such a manner that the focal point of the infrared laser light 200 is placed in the film 4. The absorptance of the infrared laser light 200 of the film 4 is higher than the absorptance of the infrared laser light 200 of the substrate 100, and is higher than the absorptance of the infrared laser light 200 of the film 5. As a result, the infrared laser light 200 emitted to the film 4 through the substrate 100 and the film 5 is efficiently absorbed by the irradiated point in the film 4, and the film 4 is made to locally generate heat (is locally heated) at the final XY plane position.

The local heat generation by the film 4 is transmitted to the film 5 and causes the film 5 to expand at the final XY plane position, as illustrated in FIG. 6C. The thermal expansion coefficient of the film 5 is larger than the thermal expansion coefficient of the substrate 100 and is larger than the thermal expansion coefficient of the film 4. As a result, at the final XY plane position, due to the expansion of the film 5, the protrusions 5a2 protruding to the +Z side in the main surface 5a on the +Z side and the protrusions 4b2 protruding to the −Z side in the main surface 5b on the −Z side in the film 5 are formed. In a manner corresponding to the above, the recesses 100b2 recessed to the +Z side in the main surface 100b on the −Z side of the substrate 100 is formed, and the recesses 4a2 recessed to the −Z side in the main surface 4a on the +Z side of the film 4 is formed.

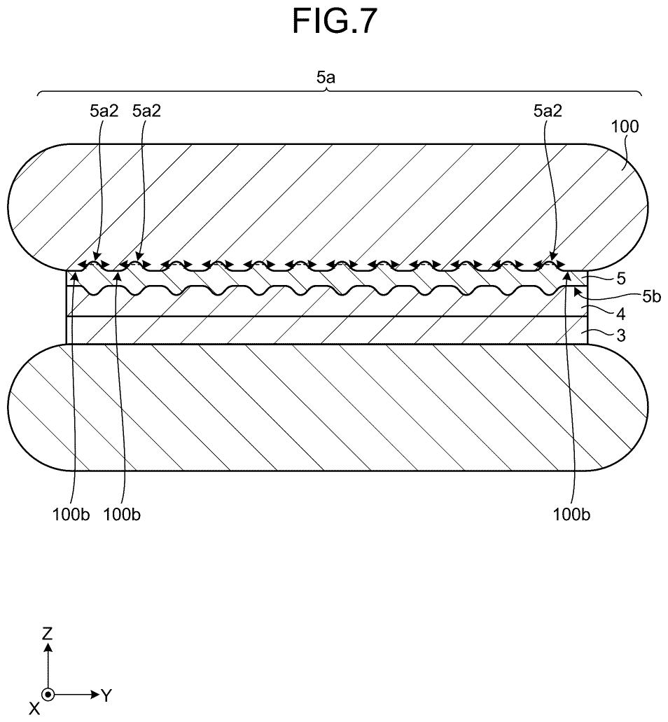

Since the emission of the infrared laser light 200 is performed in such a manner that the plural irradiated portions are two-dimensionally distributed in the film 4, the main surface 5a on the +Z side of the film 5 has protrusions two-dimensionally distributed, as illustrated in FIG. 7 and FIG. 8. On the main surface 5a, the plural protrusions 5b2 are arranged apart from each other in the XY direction. As a result, as indicated by dotted arrows in FIG. 7 and FIG. 8, local stress with which each of the plural protrusions 5a2 on the main surface 5a push out the substrate 100 to the outside in the XY direction in the vicinity of the main surface 100b may be generated.

Note that in each of an interface between the film 5 and the substrate 100 and an interface between the film 5 and the film 4, local stress is generated at plural places apart from each other in the XY direction. When a difference between the thermal expansion coefficients of the film 5 and the substrate 100 is larger than a difference between the thermal expansion coefficients of the film 5 and the film 4, the local stress generated at the interface between the film 5 and the substrate 100 is larger than the local stress generated at the interface between the film 5 and the film 4. In FIG. 7 and FIG. 8, for simplification, the relatively large local stress generated in the interface between the film 5 and the substrate 100 is selectively illustrated.

That is, the local stress is generated at the plural places apart from each other in the XY direction at the interface between the film 5 and the substrate 100, whereby non-uniformity of the joint state at the interface is generated and joining force at the interface is weakened. At this time, the interface between the film 5 and the substrate 100 becomes a surface that is easily peeled off.

Accordingly, peeling is performed at the interface between the film 5 and the substrate 100 (S6). In the peeling, as illustrated in FIG. 9A, the substrate 100 is peeled off from the stacked body 6 in which the film 3, the film 4, and the film 5 are stacked on the substrate 2. For example, a tip of a blade member 300 is inserted into the interface between the main surface 5a of the film 5 and the main surface 100b of the substrate 100. The tip of the blade member 300 has a sharp shape forming an acute angle. Since the joining force at the interface is weakened, the substrate 100 is easily peeled off from the stacked body 6 by relatively small stress by the insertion of the tip of the blade member 300.

In consideration of the subsequent processing and the like, the peeled surface of the stacked body 6 is treated as illustrated in FIG. 2 (S7). In the stacked body 6, the plural protrusions 5a2 are distributed in the XY direction on the main surface 5a on the +Z side of the film 5, as illustrated in FIG. 9B. The main surface 5a is polished and planarized by the CMP method or the like. As a result, as illustrated in FIG. 9C, the semiconductor device 1 in which the film 3, the film 4, and the film 5 are stacked on the substrate 2 and the main surface 5a of the film 5 is planarized (see FIG. 1) is acquired.

On the other hand, the peeled substrate 100 is reused as illustrated in FIG. 2 (S8). The substrate 100 may be reused as the upper substrate 100 as indicated by a solid arrow in FIG. 2.

As illustrated in FIG. 9D, in the substrate 100 immediately after the peeling, the plural recesses 100b2 are distributed in the XY direction in the main surface 100b on the −Z side. The main surface 100b is polished and planarized by the CMP method or the like. As a result, as illustrated in FIG. 9E, the substrate 100 in which the main surface 100b is planarized is acquired. The substrate 100 illustrated in FIG. 9E can be easily reused, for example, as the upper substrate 100 since the main surface 100b is planarized.

Note that as indicated by a dotted arrow in FIG. 2, the peeled substrate 100 may be reused as the lower substrate 2 instead of being reused as the upper substrate 100.

As described above, in the present embodiment, after the substrate 2 on which the film 3 is stacked and the substrate 100 on which the film 5 and the film 4 are stacked are joined, the infrared laser light 200 is emitted from the side of the substrate 100 in such a manner that the focal point is placed in the vicinity of the film 4. For example, the emission of the infrared laser light 200 is performed in such a manner that plural irradiated portions are two-dimensionally distributed in the film 4. As a result, for example, local stress can be generated at plural two-dimensionally apart places in the interface between the film 4 and the substrate 100, and the joining force at the interface can be weakened. As a result, the substrate 100 can be peeled off by the small stress by the blade member 300 or the like, and the semiconductor device 1 and the substrate 100 can be acquired. As a result, since the semiconductor device 1 and the substrate 100 can be acquired while damage at the time of peeling can be suppressed, a manufacturing yield of the semiconductor device 1 can be improved, and the substrate 100 can be easily reused. That is, the substrate 100 can be appropriately peeled off at the time of manufacturing the semiconductor device 1.

In addition, in the semiconductor device 1 in the present embodiment, the film 3, the film 4, and the film 5 are stacked on the substrate 2, the main surface 5b on the substrate side of the film 5 has the protrusions 5b2 two-dimensionally distributed, and the main surface 5a of the film 5 is planarized. The plural protrusions 5b2 is arranged on the main surface 5b. The plural protrusions 5b2 are apart from each other in a direction along the main surface 5b. The infrared light absorptance of the film 4 is higher than the infrared light absorptance of the film 5. The thermal expansion coefficient of the film 5 is larger than the thermal expansion coefficient of the film 4. This configuration is suitable for peeling the substrate 100 by weakening the joining force at the interface between the film 5 and the substrate 100 with the infrared laser light 200 after joining of the plural substrates 2 and 100. According to such a configuration, it is possible to provide the semiconductor device 1 suitable for appropriate peeling of the substrate 100.

For example, when a semiconductor device is manufactured by joining of plural substrates, there is a case where a substrate is removed by grinding processing. In this case, the removed substrate is discarded.

On the other hand, in the present embodiment, since the removed substrate 100 can be reused, it is possible to expect a significant cost reduction such as a reduction in a cost of newly preparing the substrate 100.

Alternatively, when a semiconductor device is manufactured by joining of plural substrates, there is a case where a substrate to be removed is joined via a release layer, and then the entire substrate is heated at a high temperature to weaken the release layer by thermal modification and the substrate is peeled off from the release layer. In this case, since the entire substrates are heated at a high temperature, a device structure (such as structure of the memory cell array and a structure of the control circuit) may be thermally damaged.

On the other hand, in the present embodiment, since the heating of the film 4 by the infrared laser light 200 is local heating and the heat treatment of the entire substrates is limited to a relatively low temperature (such as about 200° C.), thermal damage to a device structure (such as structure of the memory cell array or structure of the control circuit) can be suppressed.

Alternatively, when a semiconductor device is manufactured by joining of plural substrates, there is a case where a substrate is mechanically removed by relatively large stress by insertion of a blade member. In this case, the substrate to be removed may be subjected to mechanical damage such as generation of a crack.

On the other hand, in the present embodiment, the substrate 100 is removed by the small stress by the insertion of the blade member in a state in which the emission of the infrared laser light 200 is performed in such a manner that the plural irradiated portions are two-dimensionally distributed in the film 4 and the joining force at the interface between the film 5 and the substrate 100 is weakened. As a result, mechanical damage to the substrate to be removed can be suppressed.

Note that the peeling may be performed by utilization of a debonder device. For example, the debonder device includes a lower stage, an upper stage facing the lower stage in the Z direction, and a blade member configured to be insertable into a space between the lower stage and the upper stage. For example, in a process illustrated in FIG. 9A, in a state in which the substrate 2 is gripped by the lower stage and the substrate 100 is gripped by the upper stage, the tip of the blade member is inserted in the XY direction at a Z position of the interface between the film 5 and the substrate 100, and the substrate 100 is moved away from the lower stage in the +Z direction by the upper stage. As a result, the process illustrated in FIG. 9A can be executed.

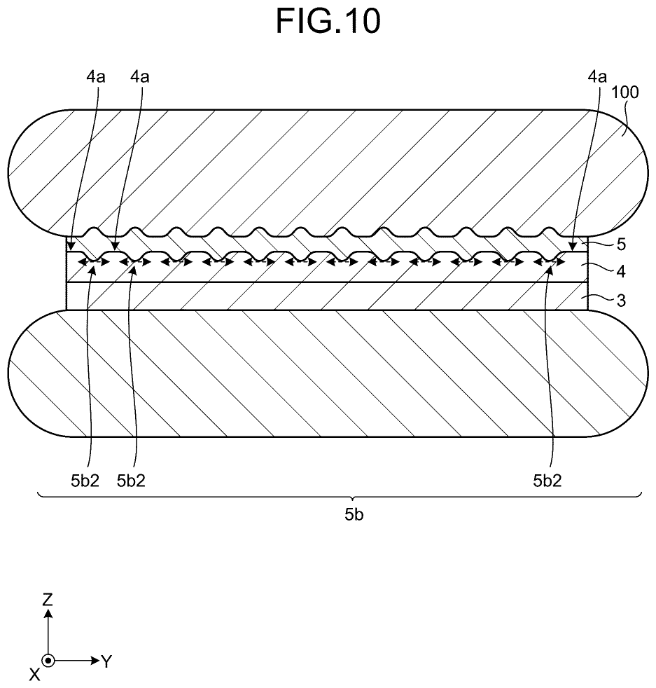

Furthermore, as a first modification example, peeling of a substrate 100 may be realized by peeling at a main surface 5b on a −Z side of a film 5 instead of peeling at a main surface 5a on a +Z side of the film 5. For example, when a difference between thermal expansion coefficients of the film 5 and a film 4 is larger than a difference between thermal expansion coefficients of the film 5 and the substrate 100, local stress generated at an interface between the film 5 and the film 4 is larger than local stress generated at an interface between the film 5 and the substrate 100. In this case, after a process illustrated in FIG. 6C, as indicated by dotted arrows in FIG. 10, local stress with which each of plural protrusions 5b2 on the main surface 5b push out the film 4 to the outside in an XY direction in the vicinity of a main surface 4a may be generated. That is, local stress is generated at plural places apart from each other in the XY direction at the interface between the film 5 and the film 4, whereby non-uniformity of a joint state at the interface is generated and joining force at the interface is weakened. At this time, the interface between the film 5 and the film 4 becomes a surface that is easily peeled off.

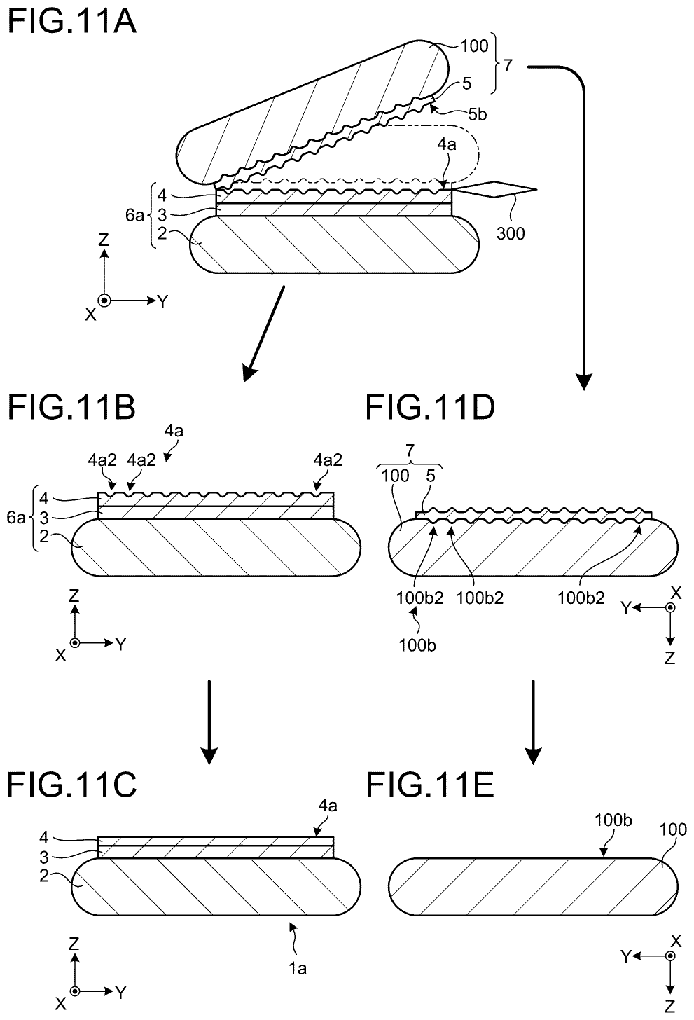

Accordingly, peeling is performed at the interface between the film 5 and the film 4 (S6). In the peeling, as illustrated in FIG. 11A, a stacked body 7 in which the film 5 is stacked on the substrate 100 is peeled off from a stacked body 6a in which a film 3 and the film 4 are stacked on a substrate 2. For example, a tip of a blade member 300 is inserted into an interface between the main surface 5b of the film 5 and the main surface 4a of the film 4. The tip of the blade member 300 has a sharp shape forming an acute angle. Since the joining force at the interface is weakened, the stacked body 7 is easily peeled off from the stacked body 6a by relatively small stress by the insertion of the tip of the blade member 300.

In consideration of the subsequent processing and the like, the peeled surface of the stacked body 6a is treated (S7). In the stacked body 6a, plural recesses 4a2 are distributed in the XY direction in the main surface 4a on the +Z side of the film 4, as illustrated in FIG. 11B. The main surface 4a is polished and planarized by the CMP method or the like. As a result, as illustrated in FIG. 11C, a semiconductor device 1a in which the film 3 and the film 4 are stacked on the substrate 2 and the main surface 4a of the film 4 is planarized is acquired.

On the other hand, the peeled substrate 100 is reused (S8). As illustrated in FIG. 11D, in the substrate 100 immediately after the peeling, a main surface 100b on the −Z side is covered with the film 5, and plural recesses 100b2 are distributed in the XY direction in the main surface 100b. After the film 5 is removed by dry etching or wet etching, the main surface 100b is polished and planarized by the CMP method or the like. As a result, as illustrated in FIG. 11E, the substrate 100 in which the main surface 100b is planarized is acquired. The substrate 100 illustrated in FIG. 11E can be easily reused, for example, as an upper substrate 100 since the main surface 100b is planarized.

In such a manner, since it is possible to acquire the semiconductor device 1 and the substrate 100 by the manufacturing method illustrated in FIG. 10 and FIG. 11A to FIG. 11E while suppressing damage at the time of peeling, a manufacturing yield of the semiconductor device 1 can be improved, and the substrate 100 can be easily reused.

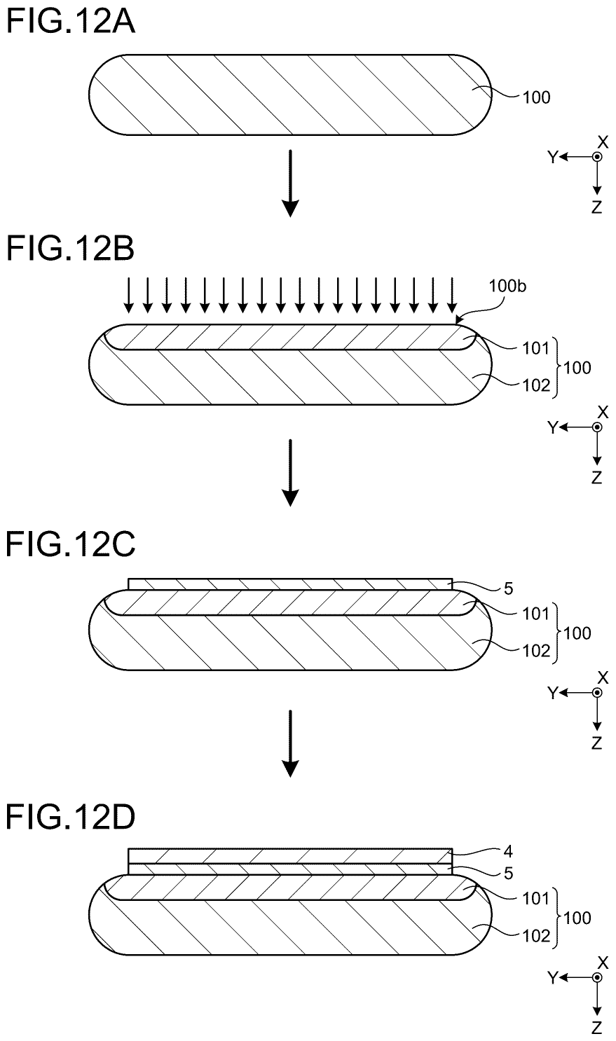

In addition, a measure to promote peeling may be taken. For example, as a second modification example, processes illustrated in FIG. 12A to FIG. 12D may be performed instead of processes illustrated in FIG. 3C to FIG. 3E.

The following processing is performed in parallel with the processing of FIG. 3A and FIG. 3B. In preparation of an upper substrate (S2), after a substrate (upper substrate) 100 is prepared as illustrated in FIG. 12A, an impurity is introduced into a region in the vicinity of a main surface 100b in the substrate 100 by an ion implantation method or the like, as illustrated in FIG. 12B. The impurity is an impurity that lowers a thermal expansion coefficient of a semiconductor (such as silicon). The impurity may be an impurity that lowers the thermal expansion coefficient of the semiconductor more than a thermal expansion coefficient of a film 4. As a result, an impurity region 101 is formed on a −Z side of a base region 102 in the substrate 100. The impurity region 101 may be formed over substantially the entire surface of the main surface 100b. A film 5 illustrated in FIG. 12C is deposited on a side of the main surface 100b (−Z side) of the substrate 100, and a film 4 illustrated in FIG. 12D is deposited on the −Z side of the film 5.

Here, a thermal expansion coefficient of the impurity region 101 is smaller than a thermal expansion coefficient of the base region 102. A thermal expansion coefficient of the film 5 is larger than the thermal expansion coefficient of the base region 102. As a result, a difference between the thermal expansion coefficients of the film 5 and the substrate 100 (impurity region 101) is larger than the difference between the thermal expansion coefficients of the film 5 and the substrate 100 in the embodiment.

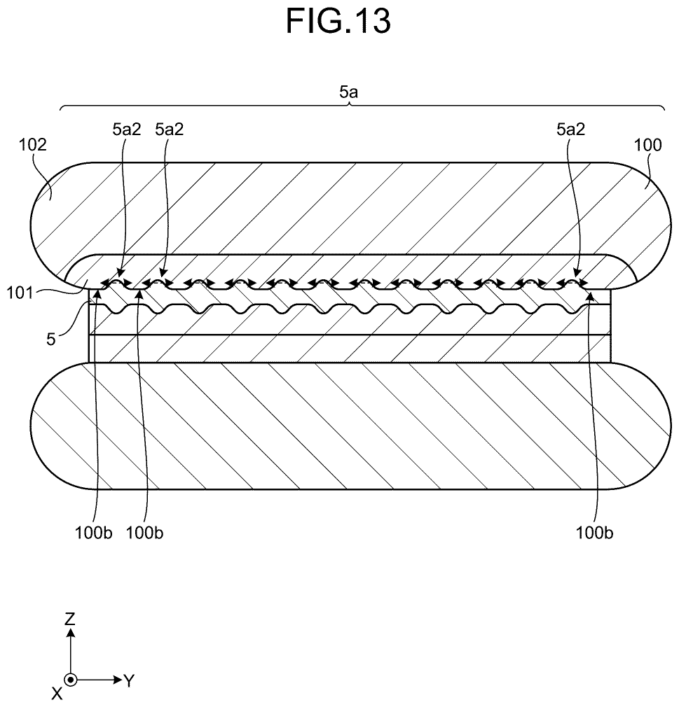

In this case, after processing illustrated in FIG. 3F to FIG. 6C is performed, as indicated by dotted arrows in FIG. 13, larger local stress with which each of plural protrusions 5b2 on a main surface 5b push out the substrate 100 to the outside in an XY direction in the vicinity of the main surface 100b may be generated. That is, the local stress is generated at plural places apart from each other in the XY direction at an interface between the film 5 and the impurity region 101, whereby non-uniformity of a joint state at the interface is increased and joining force at the interface is further weakened. At this time, as compared with the interface between the film 5 and the substrate 100 in the embodiment, the interface between the film 5 and the impurity region 101 (interface between the film 5 and the substrate 100) becomes a surface that is more easily peeled off.

Accordingly, similarly to the embodiment, peeling is performed at the interface between the film 5 and the impurity region 101 (interface between the film 5 and the substrate 100) (S6), and a semiconductor device 1a is acquired and the peeled substrate 100 is reused (S8).

As described above, according to the manufacturing method illustrated in FIG. 12A to FIG. 12D and FIG. 13, the difference between the thermal expansion coefficients of the film 5 and the substrate 100 can be increased, and the interface between the film 5 and the substrate 100 can be more easily peeled off. As a result, since the subsequent peeling of the substrate 100 can be performed by smaller stress by a blade member 300 or the like, it is possible to acquire the semiconductor device 1 and the substrate 100 while further suppressing damage at the time of the peeling.

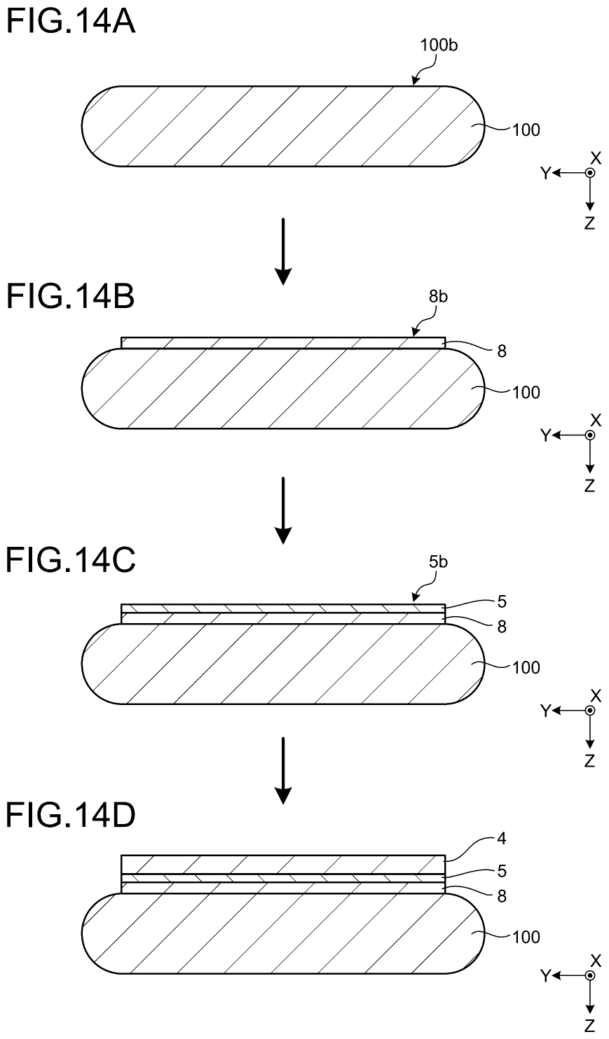

Alternatively, peeling may be promoted by addition of a film 8 instead of introduction of an impurity into a substrate 100. For example, as a third modification example, processes illustrated in FIG. 14A to FIG. 14D may be performed instead of the processes illustrated in FIG. 3C to FIG. 3E.

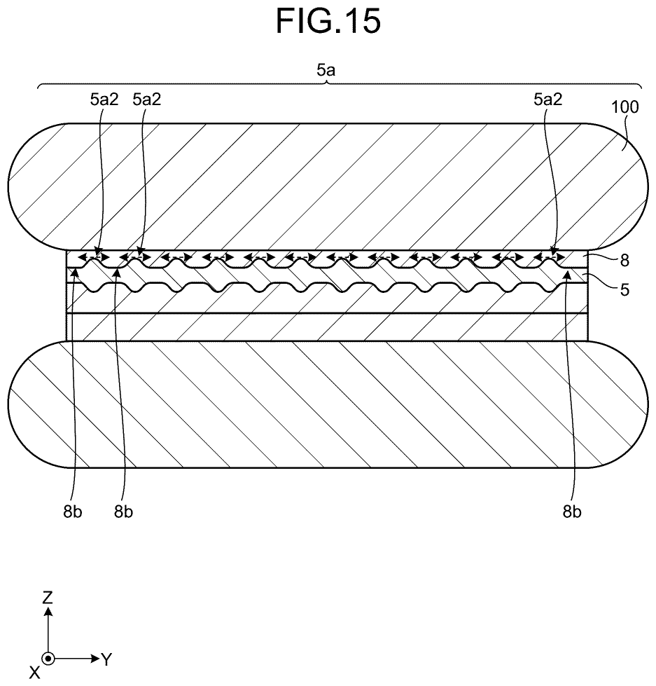

The following processing is performed in parallel with the processing of FIG. 3A and FIG. 3B. In preparation of an upper substrate (S2), after a substrate (upper substrate) 100 is prepared as illustrated in FIG. 14A, a film 8 illustrated in FIG. 14B is deposited on a side of a main surface 100b (−Z side) of a substrate 100. The film 8 may be formed of a substance having a thermal expansion coefficient smaller than that of the substrate 100. The film 8 may be formed of a substance having a thermal expansion coefficient smaller than that of the substrate 100 and smaller than that of a film 4. A film 5 illustrated in FIG. 14C is deposited on a side of a main surface 8b (−Z side) of the film 8. The film 5 can be formed of a substance having a thermal expansion coefficient larger than that of the substrate 100 (such as semiconductor polycrystalline material or semiconductor amorphous material). The film 4 illustrated in FIG. 15 is deposited on the −Z side of the film 5.

Here, a thermal expansion coefficient of the film 8 is smaller than the thermal expansion coefficient of the substrate 100. A thermal expansion coefficient of the film 5 is larger than the thermal expansion coefficient of the substrate 100. As a result, a difference between the thermal expansion coefficients of the film 5 and the film 8 is larger than the difference between the thermal expansion coefficients of the film 5 and the substrate 100 in the embodiment.

Thus, after processing illustrated in FIG. 3F to FIG. 6C is performed, as indicated by dotted arrows in FIG. 15, larger local stress with which each of plural protrusions 5a2 on a main surface 5a push out the film 8 to the outside in an XY direction in the vicinity of the main surface 8b on the −Z side of the film 8 may be generated. That is, the local stress is generated at plural places apart from each other in the XY direction at the interface between the film 5 and the film 8, whereby non-uniformity of a joint state at the interface is increased and joining force at the interface is further weakened. At this time, as compared with the interface between the film 5 and the substrate 100 in the embodiment, the interface between the film 5 and the film 8 becomes a surface that is more easily peeled off.

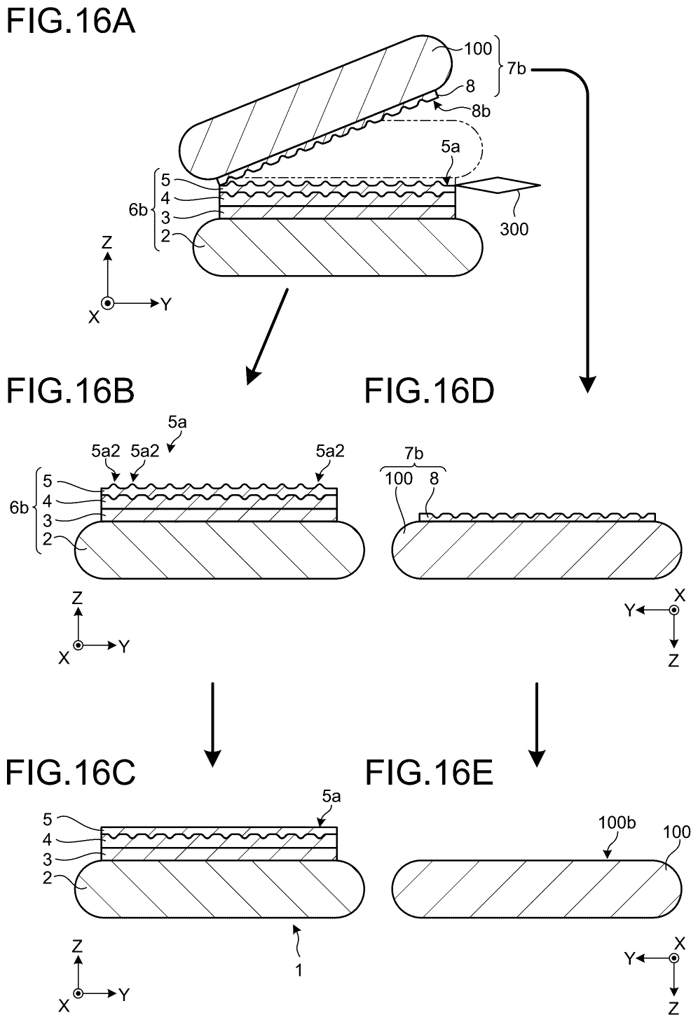

Accordingly, peeling is performed at the interface between the film 5 and the film 8 (S6). In the peeling, as illustrated in FIG. 16A, a stacked body 7b in which the film 8 is stacked on the substrate 100 is peeled off from a stacked body 6b in which a film 3, the film 4, and the film 5 are stacked on the substrate 2. For example, a tip of a blade member 300 is inserted into an interface between the main surface 8b of the film 8 and the main surface 5a of the film 5. The tip of the blade member 300 has a sharp shape forming an acute angle. Since joining force at the interface is weakened, the stacked body 7b is easily peeled off from the stacked body 6b by relatively small stress by the insertion of the tip of the blade member 300.

In consideration of the subsequent processing and the like, the peeled surface of the stacked body 6b is treated (S7). In the stacked body 6b, the plural protrusions 5a2 are distributed in the XY direction on the main surface 5a on a +Z side of the film 5, as illustrated in FIG. 16B. The main surface 5a is polished and planarized by the CMP method or the like. As a result, as illustrated in FIG. 16C, a semiconductor device 1 in which the film 3, the film 4, and the film 5 are stacked on the substrate 2, and the main surface 5a of the film 5 is planarized is acquired.

On the other hand, the peeled substrate 100 is reused (S8). As illustrated in FIG. 16D, the main surface 100b on the −Z side of the substrate 100 immediately after the peeling is covered with the film 8. The film 8 is removed by dry etching or wet etching. As a result, the substrate 100 is acquired, as illustrated in FIG. 16E. The substrate 100 illustrated in FIG. 16E is easily reused as the upper substrate 100, for example. In addition, since polishing by the CMP method or the like is not necessary, the substrate 100 can be reused in a substantially original state.

As described above, according to the manufacturing method illustrated in FIG. 14A to FIG. 16E, the difference between the thermal expansion coefficients of the film 5 and the film 8 can be increased, and the interface between the film 5 and the film 8 can be realized as an interface that is more easily peeled off as compared with the interface between the film 5 and the substrate 100 in the embodiment. As a result, since the subsequent peeling of the substrate 100 can be performed by the smaller stress by the blade member 300 or the like, it is possible to acquire the semiconductor device 1 and the substrate 100 while further suppressing damage at the time of the peeling.

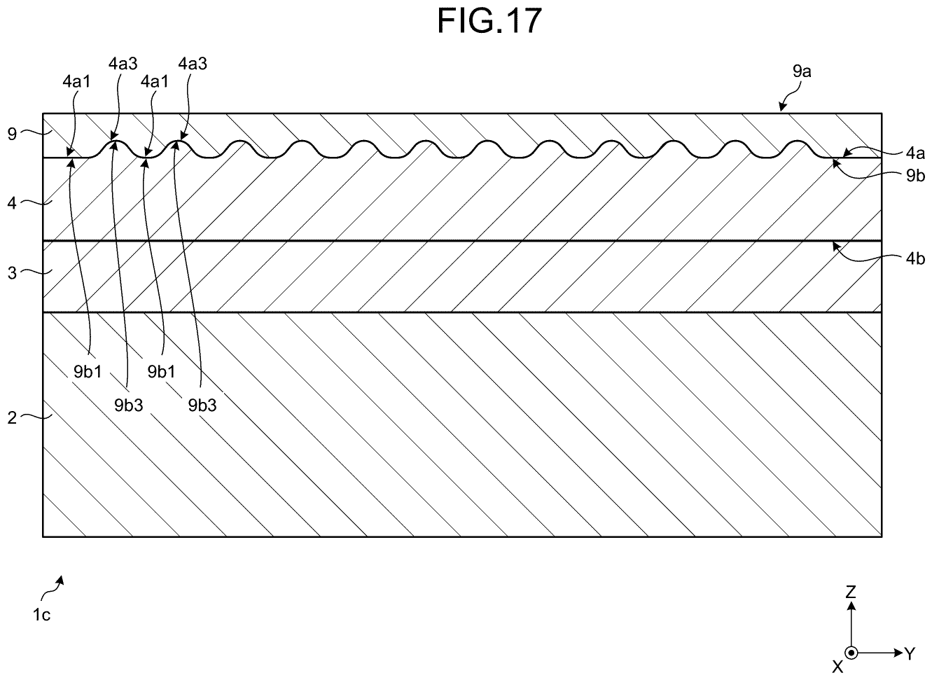

Alternatively, a semiconductor device 1c may be configured in such a manner that a thermal expansion coefficient difference is realized by addition of a film having a small thermal expansion coefficient. For example, as a fourth modification example, the semiconductor device 1c includes a film 9 instead of the film 5 (see FIG. 1) as illustrated in FIG. 17. FIG. 17 is a cross-sectional view illustrating a configuration of the semiconductor device 1c according to the fourth modification example of the embodiment.

The film 9 is arranged on the opposite side of a film 3 with a film 4 being interposed therebetween. The film 9 is arranged on a +Z side of a substrate 2, the film 3, and the film 4. The film 9 extends in an XY direction along a main surface 2a. The film 9 has a main surface 9a on the +Z side and a main surface 9b on a −Z side. Each of the main surface 9a and the main surface 9b extends in the XY direction. The main surface 9a extends in the XY direction in a flat manner.

The film 9 may be formed of any material having infrared light absorptance lower than that of the film 4, and a thermal expansion coefficient smaller than a thermal expansion coefficient of the film 4. The film 9 may be formed of any material having lower absorptance than the film 4 with respect to a laser wavelength suitable for the film 4 to function as a laser absorbing layer (preferably 1117 nm or higher, and more preferably around 9300 nm or around 10600 nm) and a thermal expansion coefficient smaller than the thermal expansion coefficient of the film 4.

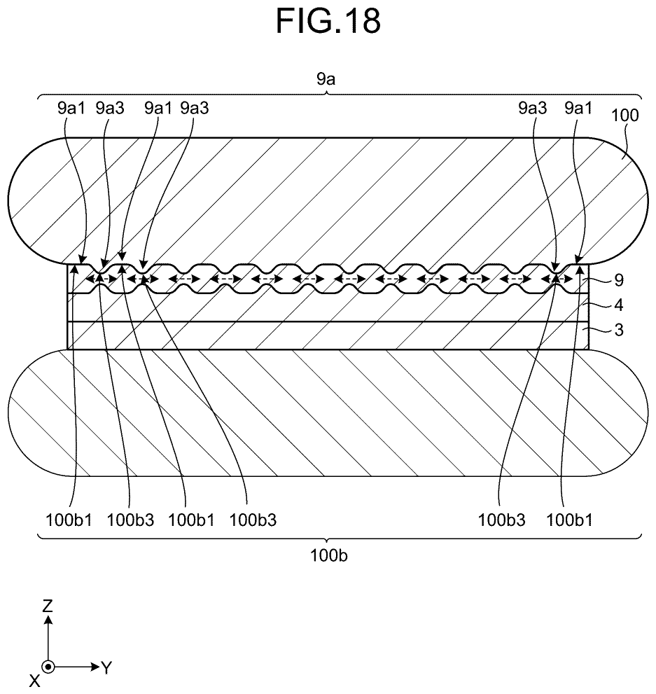

Note that the thermal expansion coefficient of the film 9 is larger than a thermal expansion coefficient of a substrate 100 arranged on the +Z side of the film 9 in a manufacturing process of the semiconductor device 1c (see FIG. 18). However, since the substrate 100 does not remain in a structure of the semiconductor device 1c, in a case where the substrate 100 is formed of the same material as the substrate 2, the thermal expansion coefficient of the film 9 is made larger than a thermal expansion coefficient of the substrate 2, whereby the thermal expansion coefficient of the film 9 can be indirectly made larger than the thermal expansion coefficient of the substrate 100.

In a case where the film 4 covers the main surface 9b of the film 9, the film 9 may be formed of any material having infrared light absorptance smaller than that of the film 4, and a thermal expansion coefficient larger than that of the substrate 2. The film 9 may be formed of any material having lower absorptance than the film 4 with respect to the laser wavelength suitable for the film 4 to function as the laser absorbing layer (preferably 1117 nm or higher, and more preferably around 9300 nm or around 10600 nm) and a thermal expansion coefficient smaller than that of the film 4.

In a case where the film 4 covers the main surface 9b of the film 9, each of a main surface 4a and the main surface 9b has protrusions or recesses two-dimensionally distributed (see FIG. 8). The main surface 4a has a flat surface 4al and plural protrusions 4a3. The flat surface 4a1 extends in the XY direction and configures a main portion of the main surface 4a. The protrusions 4a3 protrude from the flat surface 4a1 to the outside (+Z side) of the film 4. The main surface 9b has a flat surface 9b1 and plural recesses 9b3. The flat surface 9b1 extends in the XY direction and configures a main portion of the main surface 9b. The plural recesses 9b3 are arranged apart from each other in the XY direction. The recesses 9b3 are recessed from the flat surface 9b1 to the inside (+Z side) of the film 9 in a manner corresponding to the protrusions 4a3.

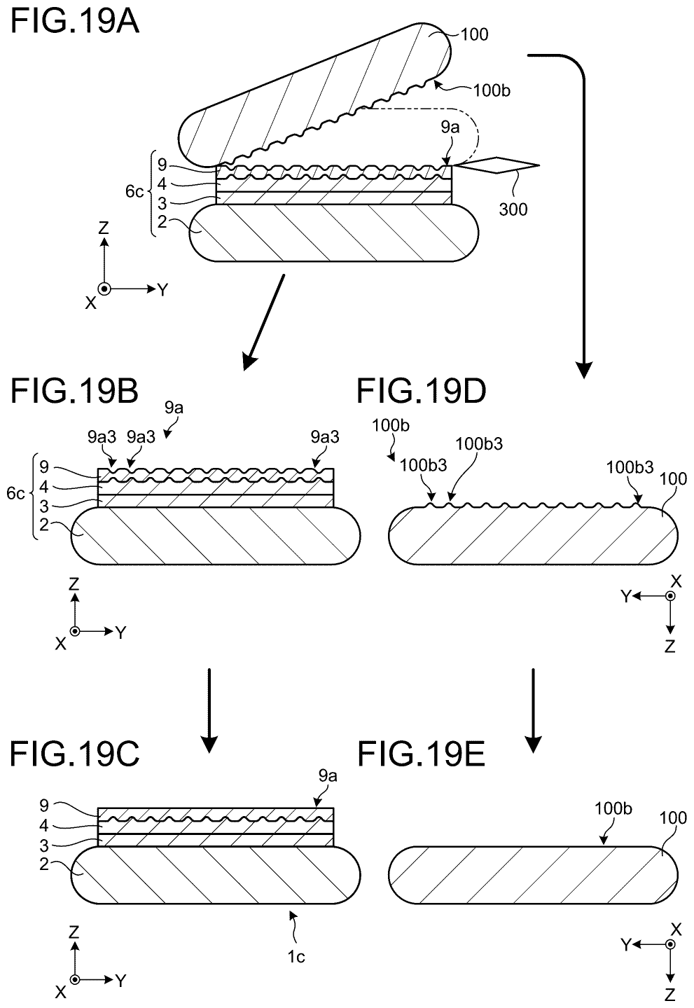

Furthermore, the semiconductor device 1c illustrated in FIG. 17 may be manufactured in a manner illustrated in FIG. 18 and FIG. 19A to FIG. 19E. Each of FIG. 18, and FIG. 19A to FIG. 19E is a YZ cross-sectional view illustrating a manufacturing method of the semiconductor device according to the fourth modification example of the embodiment.

For example, in the description of the processes of FIG. 3A to FIG. 6C, the film 5 is replaced with the film 9, “a thermal expansion coefficient larger than that of the substrate 100” is replaced with “a thermal expansion coefficient smaller than that of the substrate 100”, the main surfaces 5a and 5b are replaced with the main surfaces 9a and 9b, the protrusions 5a2 and 5b2 are replaced with the recesses 9a3 and 9b3, the recesses 100b2 are replaced with the protrusions 100b3, and the recesses 4a2 are replaced with protrusions 4b3. In a case where the processes of FIG. 3A to FIG. 6C in which these replacements are made are performed, after the process illustrated in FIG. 6C, as indicated by dotted arrows in FIG. 18, local stress with which each of the plural protrusions 100b3 on the main surface 100b push out the film 9 to the outside in the XY direction in the vicinity of the main surface 9a may be generated. That is, the local stress is generated at the plural places apart from each other in the XY direction at the interface between the film 9 and the substrate 100, whereby non-uniformity of a joint state at the interface is generated and joining force at the interface is weakened. At this time, the interface between the film 9 and the substrate 100 becomes a surface that is easily peeled off.

Accordingly, peeling is performed at the interface between the film 9 and the substrate 100 (S6). In the peeling, as illustrated in FIG. 19A, the substrate 100 is peeled off from the stacked body 6c in which the film 3, the film 4, and the film 9 are stacked on the substrate 2. For example, a tip of a blade member 300 is inserted into the interface between the main surface 100b of the substrate 100 and the main surface 9a of the film 9. The tip of the blade member 300 has a sharp shape forming an acute angle. Since the joining force at the interface is weakened, the substrate 100 is easily peeled off from the stacked body 6c by relatively small stress by the insertion of the tip of the blade member 300.

In consideration of the subsequent processing and the like, the peeled surface of the stacked body 6c is treated (S7). In the stacked body 6c, the plural recesses 9a3 are distributed in the XY direction in the main surface 9a on the +Z side of the film 9, as illustrated in FIG. 19B. The main surface 9a is polished and planarized by the CMP method or the like. As a result, as illustrated in FIG. 19C, the semiconductor device 1c in which the film 3, the film 4, and the film 9 are stacked on the substrate 2 and the main surface 9a of the film 9 is planarized is acquired.

On the other hand, the peeled substrate 100 is reused (S8). As illustrated in FIG. 19D, in the substrate 100 immediately after the peeling, the plural protrusions 100b3 are distributed in the XY direction on the main surface 100b on the −Z side. The main surface 100b is polished and planarized by the CMP method or the like. As a result, as illustrated in FIG. 19E, the substrate 100 in which the main surface 100b is planarized is acquired. The substrate 100 illustrated in FIG. 19E can be easily reused, for example, as an upper substrate 100 since the main surface 100b is planarized.

In such a manner, since it is possible to acquire the semiconductor device 1c and the substrate 100 by the manufacturing method illustrated in FIG. 18 and FIG. 19A to FIG. 19E while suppressing damage at the time of peeling, a manufacturing yield of the semiconductor device 1c can be improved, and the substrate 100 can be easily reused.

Note that although not illustrated, the peeling of the substrate 100 may be realized by peeling at the main surface 9b on the −Z side of the film 9 instead of the peeling at the main surface 9a on the +Z side of the film 9. For example, when a difference between the thermal expansion coefficients of the film 9 and the film 4 is larger than a difference between the thermal expansion coefficients of the film 9 and the substrate 100, local stress generated at an interface between the film 9 and the film 4 is larger than the local stress generated at the interface between the film 9 and the substrate 100. In this case, after the process illustrated in FIG. 6C, local stress with which each of the plural protrusions 4a3 on the main surface 4a (see FIG. 17) push out the film 9 to the outside in the XY direction in the vicinity of the main surface 9b may be generated. That is, local stress is generated at plural places apart from each other in the XY direction at the interface between the film 9 and the film 4, whereby non-uniformity of a joint state at the interface is generated and joining force at the interface is weakened. At this time, the interface between the film 9 and the film 4 becomes a surface that is easily peeled off. Accordingly, peeling (S6), treatment of the peeled surface (S7), and reuse of the peeled substrate 100 (S8) can be performed similarly to the first modification example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, the method comprising:
stacking a first film on a first substrate and stacking a third film and a second film on a second substrate;
joining a main surface on an opposite side of the first substrate of the first film and a main surface on an opposite side of the second substrate of the second film;
emitting infrared laser light from a side of the second substrate in such a manner that a focal point is placed in a vicinity of the second film; and
peeling off the second substrate,
wherein:
absorptance of the infrared laser light of the second film is higher than absorptance of the infrared laser light of the second substrate, and
a thermal expansion coefficient of the third film is different from a thermal expansion coefficient of a film in contact with the third film.

2. The manufacturing method according to claim 1, wherein absorptance of infrared pulsed laser light of the second film is higher than absorptance of the infrared pulsed laser light of the third film.

3. The manufacturing method according to claim 1, wherein the emitting includes emitting the infrared laser light in such a manner that plural irradiated portions are two-dimensionally distributed in the second film.

4. The manufacturing method according to claim 3, wherein a pulsed laser is used for the infrared laser light.

5. The manufacturing method according to claim 2, wherein:
the thermal expansion coefficient of the third film is different from a thermal expansion coefficient of the second substrate, and
the peeling includes peeling at a main surface on a side of the second substrate of the third film.

6. The manufacturing method according to claim 2, wherein:
the thermal expansion coefficient of the third film is different from a thermal expansion coefficient of a film in contact with a main surface on an opposite side of the second substrate, and
the peeling includes peeling at the main surface on the opposite side of the second substrate of the third film.

7. The manufacturing method according to claim 5, wherein:
the stacking includes stacking a fourth film, the third film, and the second film on the second substrate,
the thermal expansion coefficient of the third film is larger than the thermal expansion coefficient of the second substrate, and
a thermal expansion coefficient of the fourth film is smaller than the thermal expansion coefficient of the second substrate, and
the peeling includes peeling the second substrate by peeling the fourth film at an interface between the third film and the fourth film.

8. The manufacturing method according to claim 5, further comprising introducing an impurity that reduces the thermal expansion coefficient into the second substrate before the stacking,
wherein:
the thermal expansion coefficient of the third film is larger than a thermal expansion coefficient of the second film, and
the peeling includes peeling the second substrate at an interface between the third film and the second substrate.

9. The manufacturing method according to claim 2, further comprising polishing a surface of the second substrate after the peeling, the surface being exposed by the peeling.

10. The manufacturing method according to claim 7, further comprising removing the fourth film from the second substrate after the peeling.
